(19) United States
(12) Patent Application Publication
(10) Pub. No.: US 2026/0221940 A1
(43) Pub. Date: Jul. 30, 2026

(54) POWER CONTROL FOR A LINEAR POWER AMPLIFIER OF A TRANSMITTER

(71) Applicant: Silicon Laboratories Inc., Austin, TX (US)

(72) Inventor: Aslamali A. Rafi, Austin, TX (US)

(21) Appl. No.: 19/038,770

(22) Filed: Jan. 28, 2025

(51) Int. Cl. H03F 1/02; H03F 3/24; H04B 1/40

(52) U.S. Cl. CPC H03F 1/0205; H03F 3/245; H04B 1/40; H03F 2200/451

(57) ABSTRACT

In at least one embodiment, an apparatus includes: a power amplifier (PA) to receive and amplify a radio frequency (RF) signal; a circuit coupled to the PA to determine an output metric of the PA; and a controller coupled to the PA, the controller to control a power level of the PA to maintain a substantially constant value of a power metric, the power metric based, at least in part, on a square of the output metric and an impedance of a load coupled to the PA.

### BACKGROUND

A wireless transmitter processes and outputs a radio frequency (RF) signal. The transmitter includes a power amplifier, which amplifies the RF signal and outputs it to an antenna to radiate the signal. Especially when the wireless transmitter is included in a battery-operated device, power consumption is desirably controlled to optimize battery.

A load impedance of the antenna and other circuitry coupled to the power amplifier can change significantly, depending on design and wireless environment. Maintaining a known transmit output power under these conditions (known as voltage standing wave ratio (VSWR) is a challenge, particularly in varying load conditions, which can be due in part to a user's interaction with the device. Typically, a directional coupler is coupled to an output of the power amplifier to measure the transmitted power, and this measured power is used to regulate the output power. However a directional coupler is costly, bulky, and also results in insertion loss, and causes some output power to be wasted, which can adversely affect battery life.

### SUMMARY OF INVENTION

In one aspect, an apparatus includes: a power amplifier (PA) to receive and amplify a radio frequency (RF) signal; a circuit coupled to the PA to determine an output metric of the PA; and a controller coupled to the PA, the controller to control a power level of the PA to maintain a substantially constant value of a power metric, the power metric based, at least in part, on a square of the output metric and an impedance of a load coupled to the PA.

In an implementation, the controller is to control the power level of the PA based, at least in part, on the output metric comprising an output voltage of the PA. The controller may be configured to determine a gain of the PA based, at least in part, on the output voltage of the PA and an input voltage of a baseband signal corresponding to the RF signal.

In one implementation, the controller is to determine a coefficient based on the gain of the PA and a nominal gain of the PA for a known load impedance. The controller may be configured to infer the impedance of the load coupled to the PA based, at least in part, on the gain of the PA and the nominal gain of the PA.

In an implementation, the apparatus further includes a pre-driver coupled to an input of the PA, the pre-driver to amplify an input RF signal to provide the RF signal to the PA. The controller may be configured to determine a gain of the pre-driver based, at least in part, on the coefficient and a nominal gain of the pre-driver for the known load impedance. The controller may be configured to control the pre-driver according to the gain of the pre-driver, to control the power level of the PA to maintain the substantially constant value of the power metric. The circuit may be at least one of a voltage detector or a current detector, where the apparatus does not include a directional coupler.

In another aspect, a method includes: detecting an output metric of a PA of a transmitter during transmission of a RF signal, the transmitter comprising a baseband processor, a pre-driver, and the PA; and controlling at least one of the baseband processor or the pre-driver based at least in part on the output metric, to maintain a substantially constant value of a power metric of the PA, the power metric based, at least in part, on a square of the output metric and an impedance of a load coupled to the PA.

In one implementation, the method further comprises controlling the baseband processor to maintain the substantially constant value of the power metric when a dynamic range of the baseband processor is sufficient to cover a transmit power range for the RF signal transmission. Controlling the baseband processor may include adjusting a digital output of the baseband processor according to a scaled value of a nominal value of the output metric.

In an implementation, the method further comprises controlling the pre-driver to maintain the substantially constant value of the power metric when a dynamic range of the baseband processor is insufficient to cover a transmit power range for the RF signal transmission. Controlling the pre-driver may include updating a gain of the pre-driver based at least in part on a predetermined portion of a difference in a gain of the PA for a load impedance coupled to the PA during the transmission of the RF signal and a known load impedance coupled to the PA during characterization.

In one implementation, the method further comprises: determining a gain of the PA based, at least in part, on the output metric of the PA and an input metric of a baseband signal corresponding to the RF signal; and calculating a coefficient based on the gain of the PA and a nominal gain of the PA for a known load impedance. The method also may include: determining a gain of the pre-driver based on the coefficient and a nominal gain of the pre-driver for the known load impedance; and controlling the pre-driver according to the gain of the pre-driver, to maintain the substantially constant value of the power metric.

In yet another aspect, a system includes an antenna to transmit and receive RF signals, and, coupled to the antenna, a transceiver comprising a transmitter, a receiver, and a controller. The transmitter may include a transmit signal path comprising: an analog-to-digital converter (ADC) to covert a digital signal to an analog signal; a mixer coupled to the ADC to upconvert the analog signal to a RF signal; a pre-driver coupled to the mixer to amplify the RF signal; and a PA coupled to the pre-driver to further amplify the RF signal. The controller may be configured to control at least one of a gain of the pre-driver or a level of the digital signal, to cause a substantially constant value of a power metric of the PA to be maintained, the power metric based, at least in part, on a square of an output metric of the PA and an impedance of a load coupled to the PA, the load comprising the antenna.

In one implementation, the system further comprises a loopback path to couple an output of the PA to the receiver, where the receiver is to process the RF signal output by the PA to determine the output metric.

In an implementation, the controller is to: determine a gain of the PA based, at least in part, on the output metric of the PA and a voltage of the analog signal, the output metric of the PA comprising an output voltage; calculate a coefficient based on a comparison between the gain of the PA and a nominal gain of the PA for a known load impedance; and determine the gain of the pre-driver based, at least in part, on the coefficient and a nominal gain of the pre-driver for the known load impedance. Note that the system may be configured to determine the output metric without a directional coupler.

### BRIEF DESCRIPTION OF THE DRAWINGS

FIG. 1 is schematic illustration of an apparatus in accordance with an embodiment.

FIG. 2 is a flow diagram of a method in accordance with an embodiment.

FIG. 3 is a flow diagram of a method in accordance with an embodiment.

FIG. 4 is a block diagram of a representative integrated circuit in accordance with an embodiment.

FIG. 5 is a high level diagram of a network in accordance with an embodiment.

### DETAILED DESCRIPTION

In various embodiments, a power amplifier such as a linear power amplifier of a wireless transmitter can be controlled without presence of a directional coupler or other power-measuring component. In this way, output power of the power amplifier can be tightly controlled even in varying impedance conditions, such as may be present when the wireless transmitter is included in a device having an unknown load impedance, owing at least in part to vagaries of an environment and user interaction with the device. For example, using embodiments a variation of output power can be kept to a relatively minimal amount, e.g., less than approximately 1 decibel (dB). In contrast, directional coupler-based control techniques typically incur a much larger variation in output power, e.g., 6 dB. By tightly controlling output power even in varying load conditions, power consumption can be reduced. At the same time, the cost, bulkiness and insertion loss of a directional coupler can be avoided.

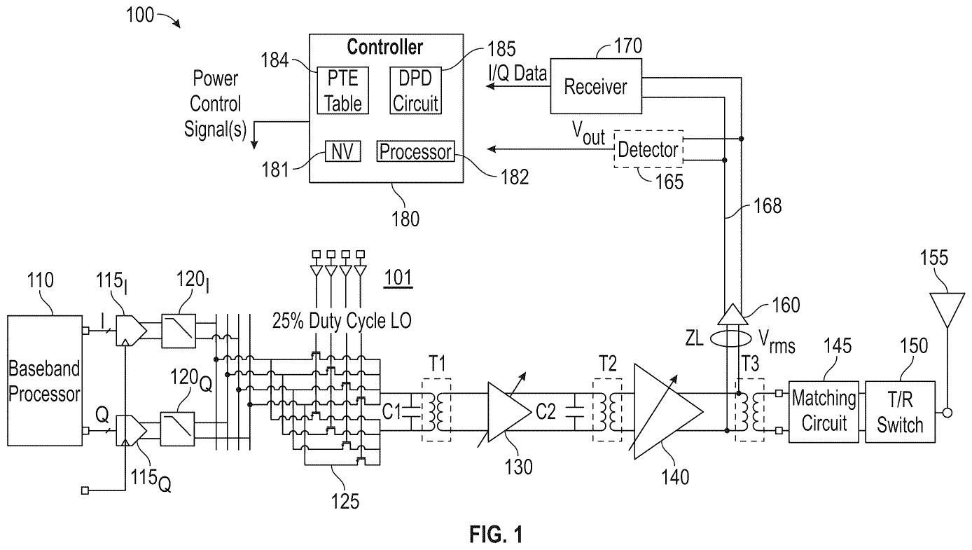

Referring now to FIG. 1, shown is schematic illustration of an apparatus in accordance with an embodiment. More specifically, in the high-level view shown in FIG. 1, apparatus 100 may be any type of wireless device including a wireless transmitter. For example, in different use cases, apparatus 100 may be an Internet of Things (IoT) device, smartphone, tablet computer, access point, wireless router, gateway device, among many other such wireless devices.

As shown, apparatus 100 includes a transmitter 101 that may be implemented as a Wi-Fi transmit path of a single or multi-protocol transceiver. In one or more implementations, apparatus 100 includes circuitry of one or more integrated circuits (ICs), such as a multi-mode wireless transceiver, and additional circuitry which may be included in one or more other ICs or as discrete components included on or coupled to a circuit board of an IoT or other such wireless device.

As shown in FIG. 1, incoming digital signals (separate digital signals for I and Q data paths) are provided from a baseband processor 110 to a pair of digital-to-analog converters (DACs) 115_{I,Q}. Understand that for these DACs and other components of the complex circuitry illustrated, numerals may be used without subscript to refer to the complex circuitry generally, and further understand that discussion of a given signal path, e.g., I or Q signal path, may apply equally to the other signal path. In an embodiment, DACs 115 may be implemented as 11-bit DACs, to receive incoming 11-bit data and convert the digital signals into analog form, namely differential complex analog signals.

In turn, the resulting analog signals are provided to corresponding to low pass filters (LPFs) 120_{I,Q}. In an embodiment, LPFs 120 may be implemented as second-order Rauch filters (and the DAC outputs may be first-order such that LPFs 120 overall are implemented as third-order filters).

As shown, LPFs 120 output filtered quadrature signals that are provided to a passive mixer 125. Mixer 125 may be implemented differentially as a complementary metal oxide semiconductor (CMOS) passive mixer having bootstrap n-channel MOSFET (NMOS) switches controlled by mixing signals such as may be received from a local oscillator (LO), which provides 25% duty cycle LO signals. In various implementations, mixer 125 may be implemented as a voltage mode passive mixer, which reduces area and current consumption (as compared to a Gilbert-cell based mixer). In turn, the resulting upconverted signals, now at RF, are provided to a pre-driver 130 via a transformer T1 (having a capacitor C1 coupled in parallel with the primary coil).

In an embodiment, pre-driver 130 may be implemented as a complementary class-AB pre-driver. Pre-driver 130 may be implemented with a plurality of units, also called “slices,” which may be independently controlled. Depending on a desired amount of gain, one or more slices of pre-driver 130 can be enabled to provide a first stage of amplification of the incoming RF signal. In the embodiment of FIG. 1, pre-driver 130 may be implemented with 64 slices that can be dynamically controlled to enable a given number of these slices, depending on desired power control level. Of course, more or fewer slices may be present in other implementations.

The resulting driven signals are provided to a transformer T2 (having a capacitor C2 coupled in parallel with the primary coil) and a secondary coil coupled to a power amplifier (PA) 140. In an embodiment, PA 140 may be implemented as a complementary class-AB amplifier having a plurality of slices that can be dynamically controlled to enable a given number of slices, depending on desired power control level. In the embodiment of FIG. 1, PA 140 may be implemented with 256 slices that can be dynamically controlled. Of course, more or fewer slices may be present in other implementations. The enabled slices operate to further amplify the corresponding RF signals.

These RF signals are output via an output transformer T3, which may be implemented as a balun, and in turn through a matching circuit 145 (which may be implemented as one or more discrete components adapted to a circuit board). Note that while the RF signals output from transformer T3 are single-ended, a ground connection of the unbalanced port of transformer T3 is coupled to matching circuit 145, to prevent formation of a parasitic antenna. In turn, the RF signals couple through a transmit/receive (T/R) switch 150 to an antenna 155 for transmission.

As further shown in FIG. 1, the amplified RF signal output from PA 140 also couples to a buffer 160. More specifically, as shown, buffer 160 couples to the primary coil of output transformer T3. This connection at the primary coil of T3 also represents the load impedance, Z_{L} and a location at which an output metric of PA 140 can be determined (e.g., an output voltage in terms of root mean square (RMS)).

With embodiments herein, the value of this load impedance, which may vary during operation, can be inferred using techniques described herein. In this way, power control can be performed to ensure that a constant “power” is output by PA 140, namely, a constant V²/|Z_{L}| is maintained, where |Z_{L}| is an absolute value of the load impedance, and V corresponds to the output voltage (Vᵣₘₛ) of PA 140. Note that the term “power” is described here in quotes, since this power metric represents not only dissipated power through the load, but also reactive power, owing to various inductances and capacitances present. In fact, this apparent “power” is the square root of the sum of the real power dissipated in the load and reactive power flowing through the inductances and capacitance present.

More particularly, in embodiments PA 140 may be controlled to maintain a substantially constant value of this power metric. Understand that as used herein, the term “substantially” is a term of approximation that encompasses both a specific value (here a constant value of V²/|Z_{L}|) as well as a small variation of this specific value (e.g., within approximately 2 dB of this constant value despite the |ZL| itself changing by 4×).

As will be described further herein, the output voltage of PA 140 can be determined in various manners. To this end, the RF output signal couples through buffer 160 to a loopback path 168 coupled to a detector 165, to measure one or more output metrics of PA 140. Note that detector 165 is illustrated in a dashed form, indicating that this component may be optional in some implementations. In one or more implementations, detector 165 can be a detector to measure a voltage level and/or current level of the output RF signal. As one particular example, detector 165 may be a peak detector configured to measure a peak voltage of the RF signal during a preamble portion of a packet of a transmission.

As also shown, buffer 160 couples through loopback path 168 to a receiver 170. Receiver 170 may process the RF signal to obtain feedback baseband information. This feedback baseband information, e.g., in the form of digital IQ data, indicates an output (e.g., voltage) level of the RF signal, and can be provided to a controller 180. In various embodiments in which transmitter 101 is implemented as a transceiver, receiver 170 further receives and process incoming RF signals. Although not shown for ease of illustration, understand that for normal receiver operation, incoming RF signals received via antenna 155 may pass through T/R switch 150 and matching circuit 145 and then through buffer 160 to receiver 170.

As discussed above, when present, detector 165 may be implemented as a voltage detector to measure the output of voltage of the RF signal output from PA 140 and provide this measured voltage to a controller 180, e.g., as a digital feedback value (Vout). Instead when detector 165 is not present, circuitry within receiver 170 may process the amplified RF signal output by PA 140 to obtain a measure of this signal's voltage, and similarly provide it as a digital value (namely I/Q data) to controller 180. In other implementations, receiver 170 may perform processing of a calibration tone, instead processing an actual RF signal being output the antenna 155. In such implementations, transmitter 101 may receive this calibration tone, e.g., from baseband processor 110 or another source and process it through the transmit path to output an amplified RF version of this calibration tone. Note that such calibration tone may be at relatively small signal levels, to avoid regulatory issues.

Controller 180 may be configured to perform power control to maintain a substantially constant value of a power metric of PA 140, e.g., V²/|Z_{L}|. To this end, controller 180 may include a processor 182, which may be a microcontroller, one or more general-purpose processing cores or so forth, to perform instructions stored in a non-transitory storage medium, such as non-volatile storage 181.

As shown in FIG. 1, controller 180 (in at least some implementations) includes a digital pre-distortion circuit 185, which can be used to digitally pre-distort baseband signals generated in baseband processor 110, to correct for non-linearities in one or more of pre-driver 130 and/or PA 140. In an embodiment in which pre-distortion circuit 185 is present (but not detector 165), controller 180 may use pre-distortion circuit 185 in determining one or more output metrics of PA 140. To this end, pre-distortion circuit 185 includes compensation tables that store compensation data, e.g., in the form of I/Q coefficients that can be applied to pre-distort digital data within baseband processor 110. These compensation tables (which may be implemented as one or more lookup tables) also provide information regarding a PA gain for given input voltage levels. In this way, based on the digital feedback information received from receiver 170, an actual PA gain can be obtained using pre-distortion circuit 185, and provided to controller 180.

In various embodiments, controller 180 may, based at least in part on feedback information including the determined output voltage and/or gain information from pre-distortion circuit 185, determine power control values. To this end, processor 182 may further access information in a table 184. As illustrated, table 184 may be implemented as a production testing (PTE) table that stores nominal values for various metrics such as certain voltages, power levels and so forth for one or more points within transmit and receive paths of apparatus 100, such as may be determined during production testing. More specifically, PTE table 184 may store certain nominal gain values for transmit circuitry as determined under nominal operating conditions (e.g., room temperature and a known load impedance, e.g., 50 Ohms).

Processor 182 may be configured to cause a substantially constant value for a power metric of PA 140 to be maintained based on the received feedback information and nominal values. In this way, processor 182 monitors at least one output metric of PA 140, and uses this monitored information along with one or more nominal values to determine appropriate settings for one or more components of the transmit signal path.

In turn, controller 180 provides power control signals to one or more components within the transmit path, including baseband processor 110, pre-driver 130 and/or PA 140. For example, controller 180 provides such power control signals to baseband processor 110 to cause adjustment to a value of digital signals output to DACs 115, and/or to pre-driver 130 and/or PA 140 to cause adjustment to a number of enabled slices. Specific control examples are described further below to cause specific control techniques based at least in part on one or more of: desired transmit power and MCS; PA output voltage; and/or load impedance. Although shown at this high level in the embodiment of FIG. 1, many variations and alternatives are possible.

In various embodiments, there may be different power control options used to control output power of a transmitter PA. As one option, output voltage of the PA (e.g., Vrms) can be controlled to be constant, irrespective of load impedance. However, such control may lead to a large variation in output power under VSWR conditions. In addition, such control may stress baseband dynamic range. In some usages, PA voltage gain can vary by nearly 12 dB across VSWR angles for VSWR=3:1. So if output voltage were to be held constant independent of VSWR, this implies that input voltage to the PA would also have to change by 12 dB, which can stress the dynamic range of baseband circuitry.

Stress on baseband dynamic range as described above can be relieved by moving at least some of the gain control to pre-driver slices. In such embodiments, RF gain (which is a product of PA gain and pre-driver gain) can be controlled to be substantially constant with antenna impedance variations. In such a control scheme, if PA gain is higher by 2× under VSWR conditions, then pre-driver gain can be controlled by enabling a selected number of pre-driver slices to be ½×, as compared to a nominal (e.g., 50 Ohms load impedance) pre-driver gain. With this control scheme, baseband circuitry is not impacted by changing PA gain.

In yet another control scheme as described herein, “power” in a load impedance ZL is maintained substantially constant. Thus if ZL is higher by 2× compared to the 50 Ohms case, then the PA output voltage is caused to be sqrt(2) higher, so that the apparent “power” is approximately kept the same.

Depending on whether sufficient baseband dynamic range is available (which may depend on one or more of target output power level and MCS), the baseband digital signal may be controlled to be scaled to cause the PA output voltage to be at a determined desired level.

In this same control case, when there is insufficient baseband dynamic range, instead of scaling the baseband signal, pre-driver circuitry can be controlled to cause the PA output voltage to be at a determined desired level. For example, if the PA load impedance is 2× higher, the PA gain is 6 dB higher. In this case pre-driver gain can be reduced by (½×) of the PA gain (expressed in dB). Thus for this case, the pre-driver gain is reduced by 3 dB. So even with an unchanged baseband signal level, the signal voltage at the PA output is −3+6=+3 dB compared to a nominal load impedance (e.g., 50 Ohms case, to cause V²/|ZL| to be maintained at a substantially constant level.

The behavior of the above 4 options under VSWR conditions can be summarized in Table 1 below. The two rows within each red box represent the 2 VSWR angle extremes. In Option 1, between the 2 rows for VSWR=3:1 the PA gain changes by +−6 dB. The PA gain in the first row is +6 dB (0 degree VSWR angle) and the second row is −6 dB (180 degree VSWR angle). The Vin column represents the voltage input to the DACs. Since pre-driver gain is unmodified for this option, the input signal needs to change by +−6 dB in order to keep the output voltage constant, which may stress baseband dynamic range as explained above.

In Option 2, since Gpre*Gpa is kept constant, the signal variation at the input of transmitter is minimized and therefore the stress on the baseband dynamic range is relieved. For option3, note that the pre-driver gain is kept constant across VSWR variation. This implies the input signal varies from −3 dB to +3 dB to keep the output “power” roughly constant. For Option 4, the deviation of pre-driver gain from the 50 ohm case is half that of the PA gain deviation from the 50 Ohm case and in the opposite direction. Thus pre-driver gain in the first row is −3 dB and the second row is +3 dB. Note there is no input signal variation in this case.

TABLE 1

| | Power | | | | | |
|---|---|---|---|---|---|---|
| | Control | | | | | |
| Option | Scheme | Vₒᵤₜ | Vᵢₙ | G_{pA} | Gₚᵣₑ | Comments |
| 1 | Constant | 0 dB | −6 dB | +6 dB | 0 dB | Large output |
| | Vout | | | | | power variation |
| | | | | | | with VSWR + |
| | | | | | | baseband DR |
| | | | | | | Stretched |
| | | 0 dB | +6 dB | −6 dB | 0 dB | |
| 2 | Constant | 0 dB | 0 dB | +6 dB | −6 dB | Large Output |
| | Vₒᵤₜ, Gₚₐ * | | | | | power variation + |
| | Gₚᵣₑ | | | | | BB signal |
| | | | | | | variation much |
| | | | | | | reduced |
| | | 0 dB | 0 dB | −6 dB | +6 dB | |
| 3 | Constant | +3 dB | +3 dB | +6 dB | 0 dB | Output Power |
| | “Power” | | | | | Variation reduced + |
| | | | | | | BB DR |
| | | | | | | stretched bit |
| | | −3 dB | −3 dB | −6 dB | 0 dB | |
| 4 | Constant | +3 dB | 0 dB | +6 dB | −3 dB | ΔGₚᵣₑ = −ΔG_{PA}/2 |
| | “Power” | −3 dB | 0 dB | −6 dB | +3 dB | Output power |
| | (with reduced | | | | | variation as well |
| | BB signal | | | | | BB signal |
| | variation) | | | | | variation much |
| | | | | | | reduced |

With embodiments that control the PA to have a substantially constant output “power,” power variation with antenna impedance variation can be significantly reduced by using Options 3 or 4.

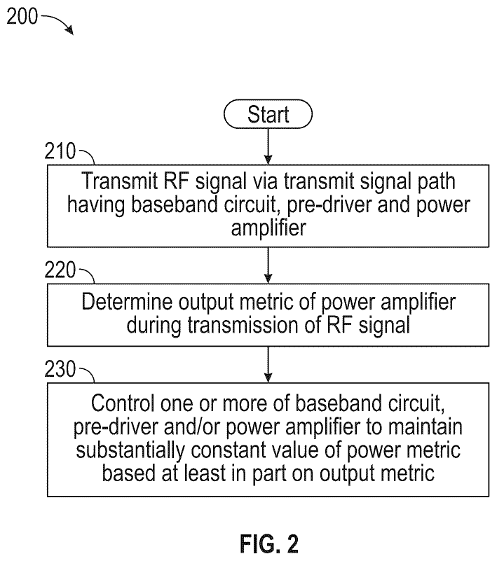

Referring now to FIG. 2, shown is a flow diagram of a method in accordance with an embodiment. As shown in FIG. 2, method 200 is a method for performing power control for a PA. In an embodiment, method 200 may be performed by hardware circuitry such as a controller alone and/or in combination with firmware and/or software. As illustrated, method 200 begins by transmitting an RF signal via a transmit signal path (block 210). Understand that this transmit signal path, such as shown in FIG. 1, includes baseband circuitry such as a baseband processor, a pre-driver and a PA. In one or more embodiments, both the pre-driver and the PA may be class-AB drivers. However in other implementations, other linear amplifiers such as class-A, class-B, or class-C pre-drivers and PAs can be controlled as described herein. Understand that the transmitted RF signal includes information of a packet communication, and may begin with communication of a preamble having known information.

Next, during transmission of the RF signal at least one output metric of the PA may be determined (block 220). In an implementation that includes a voltage detector coupled to an output of the PA, this output metric corresponds to an output voltage of the RF signal. In other cases, the detector may be implemented as a current sensor to sense a current value of the RF signal. In still further implementations, such as when no detector is present, the output metric can be determined by feeding back the RF signal through at least portions of a receiver signal path of a transceiver, in order to determine the output metric, e.g., output voltage or possibly PA gain.

Still referring to FIG. 2, next at block 230, at least one component of the transmit signal path, namely, one or more of a baseband circuit, pre-driver and/or PA, may be controlled to maintain a substantially constant value of a power metric. This power metric, in an embodiment, is according to a quadradic function, namely Vᵣₘₛ²/|Z_{L}|. More specifically, this substantially constant value may be maintained based at least in part on the determined output metric. For example, the output metric itself or another value derived using this output metric can be compared to a corresponding nominal value such as measured at a known load impedance, e.g., 50 Ohms. Based at least in part on this comparison, one or more of the components can be controlled to maintain the substantially constant value of the power metric. Although shown at this high level in the embodiment of FIG. 2, many variations and alternatives are possible. For example, in an embodiment in which a current sensor is used to measure the PA output metric, the power metric may be determined according to a different function, namely i²|Z_{L}|, where i is the measured current. As with the above discussion, in such an implementation, tight power control of the PA can be realized by maintaining a substantially constant value of this current-based power metric.

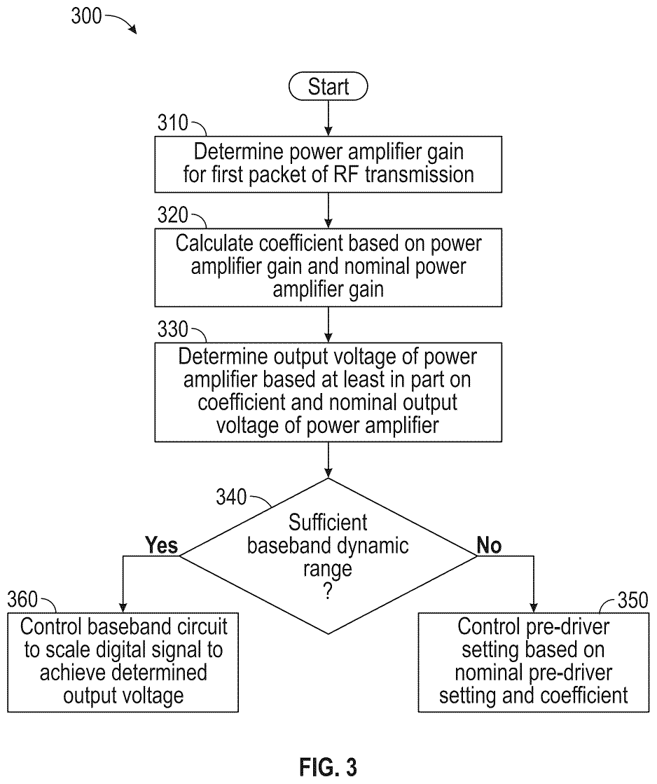

Referring now to FIG. 3, shown is a flow diagram of a method in accordance with an embodiment. As shown in FIG. 3, method 300 is a method for performing power control for a PA. In an embodiment, method 300 may be performed by hardware circuitry such as a controller alone, and/or in combination with firmware and/or software.

As shown, method 300 begins by determining a PA gain for a first packet of an RF transmission (block 310). In one embodiment, this PA gain can be determined as a voltage gain based on detection of the PA output voltage and a known input voltage. In an embodiment, this known input voltage may be a known voltage of the input signal provided from a DAC to pre-driver circuitry of the transmit path. In an embodiment, this first packet may be of a preamble portion of the packet that is transmitted with known information and at this known input voltage level. In another implementation, the gain can be determined using information obtained from a digital pre-distortion circuit as described above.

Still referring to FIG. 3, next at block 320, a coefficient may be calculated based on the PA gain and a nominal PA gain. In an embodiment, this coefficient may be calculated according to a comparison of the determined (e.g., estimated) PA gain and the nominal PA gain. In this embodiment, the calculation is according to: x=√(G_{PA}/G_{PA50}), where x is the coefficient, G_{PA} is the PA gain, and G_{PA50} is the nominal PA gain. In an embodiment, this nominal PA gain can be obtained from a non-volatile storage such as a PTE table that stores a PA gain value for a known load impedance, e.g., 50 Ohms. Note that in an embodiment in which these gain values are in terms of decibels, the ratio of G_{PA} to G_{PA50} can be calculated as a difference between these values.

Next at block 330, a target output voltage of the PA can be determined based at least in part on this coefficient and a nominal output voltage of the PA, which again may be obtained from a PTE table. Understand that this determined output voltage may be at a level to cause a substantially constant output “power” of the PA to be maintained. This output voltage may be determined in different manners in different implementations. In a particular embodiment, the output voltage can be determined to be a minimum of two different functions, where the first function is: Vsat/BO, where Vsat is a saturation voltage of the PA and BO is a threshold backoff from this value; and the second function is: Vout50*x, where Vout50 is a nominal output voltage for a known load impedance and x is the coefficient described above. In an embodiment, if the output voltage of the PA is less than the saturation voltage of the PA by less than a threshold amount (e.g., 9 dB), then Vsat can also be estimated by the signal level at which PA gain is compressed by 2 dB.

In another embodiment, the Vsat can be estimated by the gain of the PA without having to know the signal level at which the PA gain is compressed by 2 dB. This is possible because PA gain is strongly correlated with Vsat and this enables open-loop prediction of Vsat from the PA gain. In this embodiment, a table of values (PA Gain vs Vsat) is stored in the memory based on PA characterization data and for a given PA Gain, the Vsat value is interpolated based on the entries of the table in memory.

Still referring to FIG. 3, next it is determined at diamond 340 whether there is sufficient dynamic range available at baseband. In an embodiment, this determination may be based at least in part on a target output power range of the PA. For example, when this range is relatively low (e.g., 6 dB), there is sufficient dynamic range digitally to compensate for load impedance variations.

If there is not sufficient digital dynamic range, control passes to block 350, where a pre-driver setting may be controlled based on a nominal pre-driver setting and the above-determined coefficient. Understand that this nominal pre-driver setting may be a gain value of the pre-driver for a known impedance level, and can be obtained from a PTE table. In an embodiment, such control may be effected by enabling a given number of slices of the pre-driver to achieve the desired pre-driver gain. In an embodiment, this pre-driver gain may be determined according to: Gpre=Gpre50/x, where x is the coefficient, Gₚᵣₑ is the pre-driver gain, and Gₚᵣₑ₅₀ is the nominal pre-driver gain. In an embodiment, this nominal pre-driver gain can be obtained from a non-volatile storage such as a PTE table that stores a pre-driver gain value for a known load impedance, e.g., 50 Ohms.

Still referring to FIG. 3, instead if it is determined that there is sufficient baseband dynamic range, control passes to block 360. At block 360, a baseband circuit can be controlled to scale a digital signal to achieve the determined output voltage. Here, a given amount of pre-distortion may be applied to the digital signal, e.g., of a second packet following the first packet, to achieve the determined output voltage, and there is no update to pre-driver and/or PA settings.

Of course, understand while shown with these particular control techniques in the embodiment of FIG. 3, many variations and alternatives are possible. As one alternative, instead of or in addition to controlling a pre-driver setting, similar PA settings may be controlled. For example, a given number of slices of the PA can be controlled instead of or in addition to pre-driver control to effect power control that maintains a substantially constant “power” out of the PA. Although shown at this high level in the embodiment of FIG. 3, many variations and alternatives are possible. Also understand that this power control method can be performed according to a periodic interval, e.g., on the order of between approximately 1 and 3 seconds. Method 300 also may be triggered by environmental changes, such as when temperature changes by more than a threshold amount.

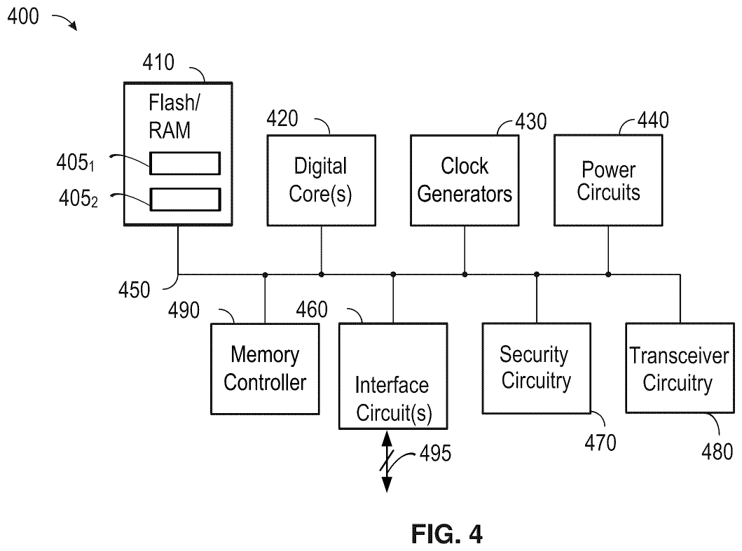

Referring now to FIG. 4, shown is a block diagram of a representative integrated circuit 400 that includes power control circuitry as described herein. In the embodiment shown in FIG. 4, integrated circuit 400 may be, e.g., a multi-mode wireless transceiver that may operate according to one or more wireless protocols or other device that can be used in a variety of use cases. In one or more embodiments, the circuitry of integrated circuit 400 shown in FIG. 4 may be implemented on a single semiconductor die or implemented on separate dies for wireless communication, MCU compute, external flash and/or other IP blocks needed to perform various functionalities.

Integrated circuit 400 may be included in a range of devices, but for purposes of discussion, it may be incorporated into an IoT device. In the embodiment shown, integrated circuit 400 includes a memory system 410 which in an embodiment may include volatile storage, such as RAM and non-volatile memory such as a flash memory. The flash memory is a non-transitory storage medium that can store instructions and data. These instructions include a set of instructions that, when executed, cause control circuitry to perform power control of various gain control elements to realize a substantially constant value of a power metric of a PA to be maintained, as described herein.

As further shown in FIG. 4, the flash memory may store a LUT 405₁ having entries including nominal gain values for various RF gain control elements including a pre-driver and PA, which may be generated, e.g., during PTE, based on a known load impedance (e.g., 50 Ohms). As further shown, memory 410 includes a LUT 405₂ to store compensation values for performing digital pre-distortion, and which may further be used in performing power control as described herein. Integrated circuit 400 also may include a memory controller 490.

Memory system 410 couples via a bus 450 to one or more digital cores 420, which may include one or more cores and/or microcontrollers that act as processing units of the integrated circuit, and which may perform power control and pre-distortion operations as described herein. In turn, digital cores 420 may couple to clock generators 430 which may provide one or more phase locked loops or other clock generator circuitry to generate various clocks for use by circuitry of the IC.

As further illustrated, IC 400 further includes power circuitry 440. Additional circuitry may be present depending on particular implementation to provide various functionality and interaction with external devices. Such circuitry may include interface circuitry 460 which provides a digital communication interface with additional circuitry (such as another IC that can couple to IC 400 via a link 495). IC 400 also may include security circuitry 470 to perform wireless security techniques.

In addition, as shown in FIG. 4, transceiver circuitry 480 may be provided to enable transmission and reception of wireless signals, e.g., according to one or more of a local area or wide area wireless communication scheme, such as Matter, Zigbee, Bluetooth, IEEE 802.11, IEEE 802.15.4, cellular communication or so forth. Understand while shown with this high level view, many variations and alternatives are possible.

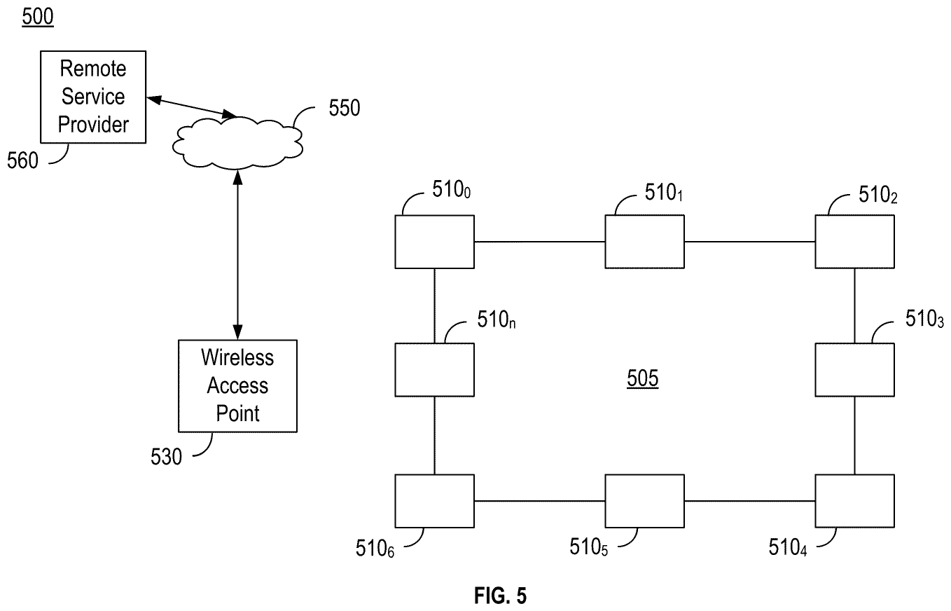

ICs such as described herein may be implemented in a variety of different devices as described above. Referring now to FIG. 5, shown is a high level diagram of a network in accordance with an embodiment. As shown in FIG. 5, a network 500 includes a variety of devices, including IoT and other wireless devices that may perform power control of a linear PA without presence of a directional coupler or other power monitor as described herein.

In the embodiment of FIG. 5, a wireless mesh network 505 is present, e.g., in a building having multiple wireless devices 5100-n. As shown, wireless devices 510, which may be IoT or other wireless devices, couple to an access point 530 that in turn communicates with a remote service provider 560 via a wide area network 550, e.g., the Internet. Understand while shown at this high level in the embodiment of FIG. 5, many variations and alternatives are possible.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
a power amplifier (PA) to receive and amplify a radio frequency (RF) signal;
a circuit coupled to the PA to determine an output metric of the PA; and
a controller coupled to the PA, the controller to control a power level of the PA to maintain a substantially constant value of a power metric, the power metric based, at least in part, on a square of the output metric and an impedance of a load coupled to the PA.

2. The apparatus of claim 1, wherein the controller is to control the power level of the PA based, at least in part, on the output metric comprising an output voltage of the PA.

3. The apparatus of claim 2, wherein the controller is to determine a gain of the PA based, at least in part, on the output voltage of the PA and an input voltage of a baseband signal corresponding to the RF signal.

4. The apparatus of claim 3, wherein the controller is to determine a coefficient based on the gain of the PA and a nominal gain of the PA for a known load impedance.

5. The apparatus of claim 4, wherein the controller is to infer the impedance of the load coupled to the PA based, at least in part, on the gain of the PA and the nominal gain of the PA.

6. The apparatus of claim 4, wherein the apparatus further comprises a pre-driver coupled to an input of the PA, the pre-driver to amplify an input RF signal to provide the RF signal to the PA.

7. The apparatus of claim 6, wherein the controller is to determine a gain of the pre-driver based, at least in part, on the coefficient and a nominal gain of the pre-driver for the known load impedance.

8. The apparatus of claim 7, wherein the controller is to control the pre-driver according to the gain of the pre-driver, to control the power level of the PA to maintain the substantially constant value of the power metric.

9. The apparatus of claim 1, wherein the circuit comprises at least one of a voltage detector or a current detector, and wherein the apparatus does not include a directional coupler.

10. A method comprising:
detecting an output metric of a power amplifier (PA) of a transmitter during transmission of a radio frequency (RF) signal, the transmitter comprising a baseband processor, a pre-driver, and the PA; and
controlling at least one of the baseband processor or the pre-driver based at least in part on the output metric, to maintain a substantially constant value of a power metric of the PA, the power metric based, at least in part, on a square of the output metric and an impedance of a load coupled to the PA.

11. The method of claim 10, further comprising controlling the baseband processor to maintain the substantially constant value of the power metric when a dynamic range of the baseband processor is sufficient to cover a transmit power range for the RF signal transmission.

12. The method of claim 11, wherein controlling the baseband processor comprises adjusting a digital output of the baseband processor according to a scaled value of a nominal value of the output metric.

13. The method of claim 10, further comprising controlling the pre-driver to maintain the substantially constant value of the power metric when a dynamic range of the baseband processor is insufficient to cover a transmit power range for the RF signal transmission.

14. The method of claim 13, wherein controlling the pre-driver comprises updating a gain of the pre-driver based at least in part on a predetermined portion of a difference in a gain of the PA for a load impedance coupled to the PA during the transmission of the RF signal and a known load impedance coupled to the PA during characterization.

15. The method of claim 10, further comprising:
determining a gain of the PA based, at least in part, on the output metric of the PA and an input metric of a baseband signal corresponding to the RF signal; and
calculating a coefficient based on the gain of the PA and a nominal gain of the PA for a known load impedance.

16. The method of claim 15, further comprising:
determining a gain of the pre-driver based on the coefficient and a nominal gain of the pre-driver for the known load impedance; and
controlling the pre-driver according to the gain of the pre-driver, to maintain the substantially constant value of the power metric.

17. A system comprising:
an antenna to transmit and receive radio frequency (RF) signals; and
a transceiver coupled to the antenna, the transceiver comprising a transmitter, a receiver, and a controller, wherein the transmitter comprises:
a transmit signal path comprising:
an analog-to-digital converter (ADC) to covert a digital signal to an analog signal;
a mixer coupled to the ADC to upconvert the analog signal to a RF signal;
a pre-driver coupled to the mixer to amplify the RF signal; and
a power amplifier (PA) coupled to the pre-driver to further amplify the RF signal; and
wherein the controller is to control at least one of a gain of the pre-driver or a level of the digital signal, to cause a substantially constant value of a power metric of the PA to be maintained, the power metric based, at least in part, on a square of an output metric of the PA and an impedance of a load coupled to the PA, the load comprising the antenna.

18. The system of claim 17, further comprising a loopback path to couple an output of the PA to the receiver, wherein the receiver is to process the RF signal output by the PA to determine the output metric.

19. The system of claim 17, wherein the controller is to:
determine a gain of the PA based, at least in part, on the output metric of the PA and a voltage of the analog signal, the output metric of the PA comprising an output voltage;
calculate a coefficient based on a comparison between the gain of the PA and a nominal gain of the PA for a known load impedance; and
determine the gain of the pre-driver based, at least in part, on the coefficient and a nominal gain of the pre-driver for the known load impedance.

20. The system of claim 17, wherein the system is to determine the output metric without a directional coupler.
